(19) United States
(12) Patent Application Publication
(10) Pub. No.: US 2026/0262463 A1
(43) Pub. Date: Sep. 3, 2026

(54) METHOD FOR DETERMINING CLEANING CONDITIONS FOR SEMICONDUCTOR WAFER, AND METHOD FOR CLEANING THE SAME

(71) Applicant: SUMCO Corporation, Tokyo (JP)

(72) Inventors: Mami KUBOTA, Tokyo (JP); Yoshiki SATO, Tokyo (JP); Haruka ODA, Tokyo (JP); Kei ASHIBA, Tokyo (JP); Fumiaki NAKAO, Tokyo (JP); Miwako YAMADA, Tokyo (JP)

(73) Assignee: SUMCO Corporation, Tokyo (JP)

(21) Appl. No.: 19/163,677

(22) PCT Filed: Feb. 26, 2024
(86) PCT No.: PCT/JP2024/006853

§ 371 Date: Sep. 9, 2025

(30) Foreign Application Priority Data
Mar. 10, 2023 (JP) 2023-038139

(51) Int. Cl. H10P 70/00; H10P 14/60; H10P 74/20

(52) U.S. Cl. CPC H10P 70/20; H10P 14/6309; H10P 14/6322; H10P 74/203

(57) ABSTRACT

Provided is a method for determining cleaning conditions for a semiconductor wafer, which enables favorable control of the thickness of a thermal oxide film. The method of this disclosure includes: obtaining a cleaning correlation between a thickness and a surface condition of a chemical oxide film formed after a cleaning process and cleaning conditions; for one or more different heat treatment conditions, obtaining a heat treatment correlation between an amount of increase in thickness of an oxide film after a heat treatment process and the thickness and the surface condition of the chemical oxide film; determining heat treatment conditions and a target thickness of the thermal oxide film-formed in the heat treatment process; and determining the cleaning conditions such that the thickness of the thermal oxide film formed in the heat treatment process becomes the target thickness.

### TECHNICAL FIELD

The present disclosure relates to a method for determining cleaning conditions for a semiconductor wafer, and a method for cleaning a semiconductor wafer.

### BACKGROUND

In a device fabrication process, a semiconductor wafer, which serves as a substrate for a semiconductor device, is subjected to a heat treatment to form a thermal oxide film on a surface of the semiconductor wafer. The thickness of the formed thermal oxide film affects characteristics of the semiconductor device to be formed on the semiconductor wafer, and variations in the thickness of the thermal oxide film affect the yield. Accordingly, it is required that the thermal oxide film be formed with a target thickness and with minimal variation.

Patent Document 1 discloses a technique for reproducibly forming a thermal oxide film having a predetermined thickness, based on the finding that the composition of a chemical oxide film formed on the surface of a semiconductor substrate by cleaning has a significant influence on the thermal oxidation treatment. In this technique, a correlation between the composition of the chemical oxide film and the thickness of the thermal oxide film is previously obtained, and a composition of the chemical oxide film that results in the predetermined thickness of the thermal oxide film is determined. Then, cleaning conditions that provide the chemical oxide film having the determined composition are determined, and the semiconductor wafer is cleaned under the cleaning conditions.

### CITATION LIST

### Patent Literature

PTL 1: JP 6791454 B

### SUMMARY

### Technical Problem

However, in order to obtain the composition of the chemical oxide film determined in the technique described in Patent Document 1, it is necessary to significantly modify the cleaning conditions. Such modifications may deteriorate surface qualities other than the thickness of the chemical oxide film after cleaning, such as particle contamination, which can lead to a reduction in device yield. Therefore, there has been a demand for a method capable of favorably controlling the thickness of the thermal oxide film without changing the composition of the chemical oxide film.

The present disclosure has been made in view of the foregoing problems, and an object thereof is to provide a method for determining cleaning conditions for a semiconductor wafer, which enables favorable control of the thickness of a thermal oxide film.

### Solution to Problem

The present disclosure, which has been made to solve the above-described problems, is as follows.

[1] A method for determining cleaning conditions of a semiconductor wafer, the method comprising:
a cleaning correlation acquisition process of preparing a plurality of semiconductor wafers that have undergone a cleaning process under a plurality of cleaning conditions, and obtaining a cleaning correlation, which is a correlation between a thickness and a surface condition of a chemical oxide film formed on a surface of each of the plurality of semiconductor wafers and the cleaning conditions;
a heat treatment correlation acquisition process of, for each of one or more different heat treatment conditions in a heat treatment process, preparing a plurality of semiconductor wafers that have undergone the heat treatment process subsequent to the cleaning process, and obtaining a heat treatment correlation, which is a correlation between an amount of increase in thickness of an oxide film after the heat treatment process with respect to a thermal oxide film formed on the surface of each of the plurality of semiconductor wafers and the thickness and the surface condition of the chemical oxide film;
a heat treatment condition determination process of determining the heat treatment conditions in the heat treatment process and determining a target thickness of the thermal oxide film to be formed on the surface of the semiconductor wafer in the heat treatment process under the determined heat treatment conditions; and
a cleaning condition determination process of determining the cleaning conditions such that the thickness of the thermal oxide film to be formed on the surface of the semiconductor wafer in the heat treatment process under the determined heat treatment conditions becomes the target thickness, based on the heat treatment correlation and the cleaning correlation.

[2] The method for determining cleaning conditions of a semiconductor wafer according to [1] above, wherein the surface condition is indicated by a power spectral density of surface roughness measured using an atomic force microscope.

[3] The method for determining cleaning conditions of a semiconductor wafer according to [1] or [2] above, wherein the heat treatment correlation is expressed by the following Equation (1), in which Y is the amount of increase in the thickness of the oxide film after the heat treatment process, X1 is the thickness of the chemical oxide film, X2 is the surface condition, and A, B, and C are constants:

$$Y = A \cdot X 1 + B \cdot X 2 + C \qquad ( 1 )$$

[4] The method for determining cleaning conditions of a semiconductor wafer according to [3] above, wherein
the constants A, B, and C are obtained in advance for each of the one or more heat treatment conditions, and
the constants A, B, and C are determined in accordance with the heat treatment conditions determined in the heat treatment condition determination process.

[5] The method for determining cleaning conditions of a semiconductor wafer according to any one of [1] to [4] above, wherein
the cleaning process includes, as at least a final step of the cleaning process, an ozone treatment process in which only ozone-dissolved water is supplied to the semiconductor wafer as a chemical solution, and wherein
among the plurality of cleaning conditions, a duration of the final step is different.

[6] The method for determining cleaning conditions of a semiconductor wafer according to any one of [1] to [4] above, wherein
the cleaning process includes:
   a hydrofluoric acid treatment process in which only hydrofluoric acid water is supplied to the semiconductor wafer as a chemical solution;
   a mixing treatment process in which hydrofluoric acid water and ozone-dissolved water are simultaneously supplied to the semiconductor wafer as chemical solutions; and
   an ozone treatment process in which only ozone-dissolved water is supplied to the semiconductor wafer as a chemical solution, and wherein
among the plurality of cleaning conditions, a duration of the mixing treatment process is different.

[7] The method for determining cleaning conditions of a semiconductor wafer according to any one of [1] to [4] above, wherein
the cleaning process includes:
   a hydrofluoric acid treatment process in which only hydrofluoric acid water is supplied to the semiconductor wafer as a chemical solution; and
   an ozone treatment process in which only ozone-dissolved water is supplied to the semiconductor wafer as a chemical solution, and wherein
among the plurality of cleaning conditions, a concentration of the ozone-dissolved water is different.

[8] The method for determining cleaning conditions of a semiconductor wafer according to any one of [1] to [4] above, wherein
the cleaning process includes:
   a hydrofluoric acid treatment process in which only hydrofluoric acid water is supplied to the semiconductor wafer as a chemical solution; and
   an ozone treatment process in which only ozone-dissolved water is supplied to the semiconductor wafer as a chemical solution, and wherein
among the plurality of cleaning conditions, a duration of a final hydrofluoric acid treatment process is different.

[9] The method for determining cleaning conditions of a semiconductor wafer according to any one of [1] to [4] above, wherein
the cleaning process includes:
   a hydrofluoric acid treatment process in which only hydrofluoric acid water is supplied to the semiconductor wafer as a chemical solution; and
   an ozone treatment process in which only ozone-dissolved water is supplied to the semiconductor wafer as a chemical solution, and wherein
among the plurality of cleaning conditions, a rotation speed of the semiconductor wafer during a final hydrofluoric acid treatment process is different.

[10] A method for cleaning a semiconductor wafer, wherein a semiconductor wafer is cleaned under the cleaning conditions determined by the method for determining cleaning conditions of a semiconductor wafer according to any one of [1] or [2] above.

[11] The method for cleaning a semiconductor wafer according to [10] above, wherein the semiconductor wafer is a silicon wafer.

### Advantageous Effect

According to the present disclosure, the thickness of a thermal oxide film can be favorably controlled. As a result, device yield can be improved, thereby achieving improvements in production efficiency and reductions in waste.

### BRIEF DESCRIPTION OF THE DRAWINGS

In the accompanying drawings:

FIG. 1 is a graph illustrating the behavior of thermal oxide film growth;

FIG. 2 is a schematic diagram for explaining the influence of the surface condition of a chemical oxide film on the formation of the thermal oxide film, where (a) illustrates a case in which the surface roughness is small, and (b) illustrates a case in which the surface roughness is large;

FIG. 3 is a flowchart illustrating a method for determining cleaning conditions for a semiconductor wafer according to the present disclosure;

FIG. 4 is a diagram illustrating (a) measurement positions for power spectral density by AFM, and (b) an example of the measured power spectral density;

FIG. 5 is a diagram illustrating (a) the configuration of a cleaning process, and (b) the relationship between the time of a final ozone treatment process and the thickness of a chemical oxide film;

FIG. 6 is a diagram illustrating the ratio of the time of a mixing treatment process to the total time of the cleaning process, where (a) is an example of 0%, (b) is an example of 25%, (c) is an example of 50%, and (d) is an example of 100%;

FIG. 7 is a plot illustrating the relationship between the ratio of the mixing treatment process and the power spectral density ratio;

FIG. 8 is a diagram illustrating (a) the configuration of a cleaning process, and (b) the relationship between the time of a final hydrofluoric acid treatment process and the power spectral density ratio;

FIG. 9 is a diagram illustrating (a) the configuration of a cleaning process, and (b) the relationship between the concentration of ozone-dissolved water and the power spectral density ratio;

FIG. 10 is a diagram illustrating the relationship between a predicted value and a measured value of an increase in the thickness of the oxide film after a heat treatment process; and

FIG. 11 is a diagram illustrating (a) the thicknesses of thermal oxide films for three different devices in Conventional Example, and (b) the thicknesses of thermal oxide films in Conventional Example and in Example 2.

### DETAILED DESCRIPTION

### (Method for Determining Cleaning Conditions of a Semiconductor Wafer)

Hereinafter, embodiments of the present disclosure will be described with reference to the drawings. The method for determining cleaning conditions of a semiconductor wafer according to the present disclosure includes: a cleaning correlation acquisition process of preparing a plurality of semiconductor wafers that have undergone a cleaning process under a plurality of cleaning conditions, and obtaining a cleaning correlation, which is a correlation between a thickness and a surface condition of a chemical oxide film formed on a surface of each of the plurality of semiconductor wafers and the cleaning conditions; a heat treatment correlation acquisition process of, for each of one or more different heat treatment conditions in a heat treatment process, preparing a plurality of semiconductor wafers that have undergone the heat treatment process subsequent to the cleaning process, and obtaining a heat treatment correlation, which is a correlation between an amount of increase in thickness of an oxide film after the heat treatment process with respect to a thermal oxide film formed on the surface of each of the plurality of semiconductor wafers and the thickness and the surface condition of the chemical oxide film; a heat treatment condition determination process of determining the heat treatment conditions in the heat treatment process and determining a target thickness of the thermal oxide film to be formed on the surface of the semiconductor wafer in the heat treatment process under the determined heat treatment conditions; and a cleaning condition determination process of determining the cleaning conditions such that the thickness of the thermal oxide film to be formed on the surface of the semiconductor wafer in the heat treatment process under the determined heat treatment conditions becomes the target thickness, based on the heat treatment correlation and the cleaning correlation.

The present inventors have conducted intensive studies on methods for more effectively controlling the thickness of a thermal oxide film to be formed on the surface of a semiconductor wafer during a heat treatment process. The thermal oxide film is formed by oxygen diffusing inward from the surface of a chemical oxide film (natural oxide film) that has already been formed in a prior process such as a cleaning process, and chemically reacting with constituent elements of the semiconductor wafer at the interface between the chemical oxide film and the semiconductor wafer.

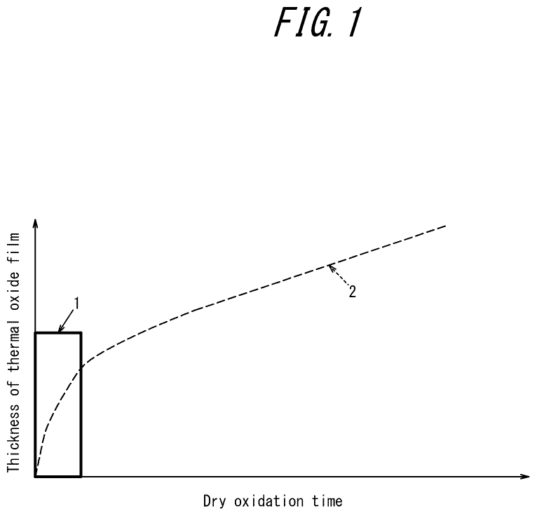

As given in FIG. 1, it is known that the growth behavior of the oxide film differs between a region where the film thickness is small (region 1 in the figure) and a region where the thickness is large (region 2 in the figure). Conventionally, according to the Deal-Grove model, it has been believed that in the region 1 with a small oxide film thickness, the formation of the oxide film is rate-limited by the reaction between the constituent elements of the semiconductor wafer and oxygen, whereas in the region 2 with a large oxide film thickness, the formation is rate-limited by the diffusion of oxygen. However, recent studies have reported that even in the region 1, the formation of the oxide film is rate-limited by the diffusion of oxygen (see, for example, T. Watanabe, K. Tatsumura, I. Ohdomari, Phys. Rev. Lett., 96, 196102 (2006)). In device fabrication processes, the thermal oxide films formed typically have a thickness of about 30 to 50 Å, which corresponds to the region 1. Therefore, in order to control the thickness of the thermal oxide film to a target value, it is necessary to control the diffusion of oxygen within the oxide film.

In the course of intensive studies aimed at controlling the thickness of the thermal oxide film to be formed during the heat treatment process by regulating the diffusion of oxygen within the oxide film, the present inventors discovered that there is a favorable correlation between the thickness and surface condition of the chemical oxide film formed on the surface of the semiconductor wafer during the cleaning process, and an increase in thickness of a oxide film after the heat treatment process with respect to the thermal oxide film formed on the surface of the semiconductor wafers.

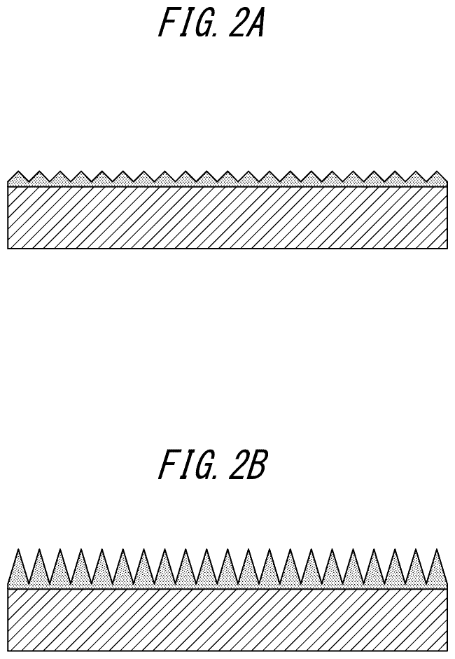

That is, when the chemical oxide film has a greater thickness, the oxygen taken in from the surface of the chemical oxide film takes more time to reach the interface between the chemical oxide film and the semiconductor wafer. Therefore, it is considered that a greater thickness of the chemical oxide film results in a slower arrival of oxygen at the interface between the chemical oxide film and the semiconductor wafer. On the other hand, regarding the surface condition of the chemical oxide film, as illustrated in FIG. 2(a), for example, when the surface roughness is small, the specific surface area of the chemical oxide film is also small, making it more difficult for oxygen to be taken in from the surface of the chemical oxide film. In contrast, as illustrated in FIG. 2(b), when the surface roughness of the chemical oxide film is large, the specific surface area of the chemical oxide film increases, and it is considered that oxygen is more readily taken in from the surface of the chemical oxide film.

Based on the above findings, the present inventors determined that by first obtaining: the correlation between the thickness and surface condition of the chemical oxide film formed on the surface of the semiconductor wafer during the cleaning process and the cleaning conditions (hereinafter, the “cleaning correlation”), and the correlation between the thickness and surface condition of the chemical oxide film, as well as each of one or more heat treatment conditions, and the amount of increase in the thickness of the oxide film after the heat treatment process, with respect to the thermal oxide film formed on the surfaces of semiconductor wafers in the heat treatment process (heat treatment correlation), and then determining the heat treatment conditions as well as the target thickness of the thermal oxide film to be formed during the heat treatment process under the determined heat treatment conditions, it becomes possible to determine cleaning conditions that enable favorable control of the thickness of the thermal oxide film to be formed during the heat treatment process. This discovery led to the completion of the present disclosure. The following sections describe each process in detail.

### <Cleaning Correlation Acquisition Process>

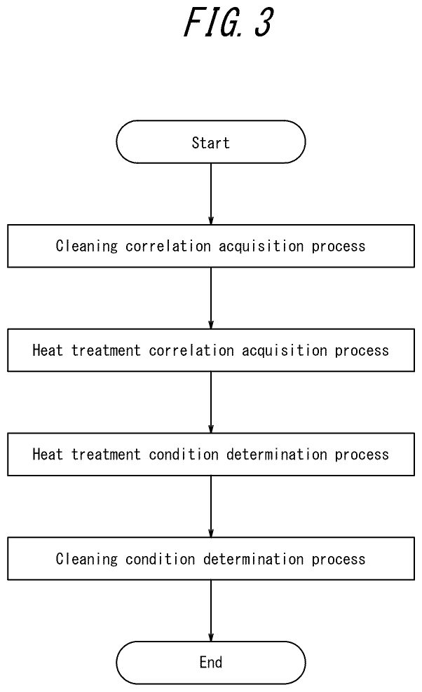

FIG. 3 illustrates a flowchart of the method for determining cleaning conditions for a semiconductor wafer according to the present disclosure. First, a plurality of semiconductor wafers that have undergone a cleaning process under a plurality of cleaning conditions are prepared. Then, the correlation (cleaning correlation) between the thickness and surface condition of the chemical oxide film formed on the surface of each of the semiconductor wafers, and the corresponding cleaning conditions is obtained.

The semiconductor wafers used to obtain the cleaning correlation are not particularly limited and may include bulk single-crystal wafers composed of silicon, germanium, or compound semiconductors such as GaAs, GaN, or SiC. For example, the semiconductor wafer may be one obtained by slicing a single-crystal ingot of silicon or the like, grown by the Czochralski (CZ) method or the Floating Zone (FZ) method, using a wire saw or the like. To impart gettering capability against heavy metals, the semiconductor wafer may optionally be doped with carbon and/or nitrogen. Furthermore, any dopant may be added to the semiconductor wafer in a predetermined concentration, so that the wafer becomes an n⁺-type, p⁺-type, n⁻-type, or p⁻-type semiconductor wafer.

Alternatively, a semiconductor epitaxial wafer, in which a semiconductor epitaxial layer is formed on the surface of a bulk semiconductor wafer, may be used as the semiconductor wafer. For example, an epitaxial silicon wafer having a silicon epitaxial layer formed on the surface of a bulk single-crystal silicon wafer can be used as such a semiconductor epitaxial wafer. The silicon epitaxial layer can be formed under general conditions by a chemical vapor deposition (CVD) method.

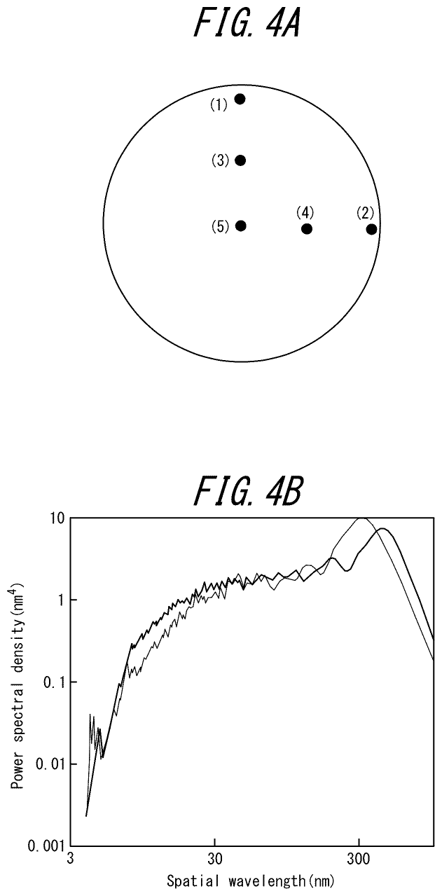

The thickness of the chemical oxide film can be measured, for example, by ellipsometry at a region on the surface of the semiconductor wafer. When measuring the thickness of the chemical oxide film using ellipsometry, the thickness can be measured at multiple positions on the surface of the semiconductor wafer, such as at five points: the center (5), the outer periphery (1) and (2), and the positions at half the wafer radius (R/2), i.e., points (3) and (4), as illustrated in FIG. 4(a) (for example, using a measurement area of 1 μm). The average of these values may be used as the thickness of the chemical oxide film

The surface condition of the chemical oxide film may be, for example, defined by surface roughness. As illustrated in FIG. 4(b), the surface condition of the chemical oxide film can be indicated, for instance, by the power spectral density (PSD) of surface roughness measured using an atomic force microscope (AFM). As a result of the inventors' investigations, it was found that there exists a favorable monotonic relationship between the integrated value of the power spectral density in a relatively small spatial wavelength range, such as 3.9 nm to 10 nm, and the thickness of the thermal oxide film formed during the heat treatment process. Accordingly, when the surface condition of the chemical oxide film is indicated by the power spectral density of the surface roughness measured using AFM, it is preferable to use the integrated value of the power spectral density within the relatively small spatial wavelength range.

It is preferable to measure the lower limit of the above-mentioned spatial wavelength range starting from as small a wavelength as possible; for example, preferably from 3.9 nm, more preferably from 1 nm, and even more preferably from a value greater than 0 nm and less than 1 nm. On the other hand, the upper limit of the spatial wavelength range is preferably set to 10 nm.

The surface condition of the chemical oxide film may also be evaluated using the ratio of the integrated value of the power spectral density over a relatively small spatial wavelength range (e.g., 3.9 nm to 10 nm) to the integrated value over the entire range (e.g., 3.9 nm to 100 nm) measured by an atomic force microscopy (AFM), as an index (referred to as the “power spectral density ratio”).

Furthermore, the surface condition of the chemical oxide film may also be evaluated using the root mean square roughness (Rq), limited to a specific spatial wavelength range, measured by an atomic force microscopy (AFM). For example, an image may be generated by extracting only the components within a wavelength range such as 25 to 80 nm, and the Rq calculated from this image can be used as an index.

The cleaning process performed on the semiconductor wafer may be a cleaning process in a semiconductor wafer manufacturing process. The cleaning process in the semiconductor wafer manufacturing process may include a hydrofluoric acid treatment process in which only hydrofluoric acid water is supplied to the semiconductor wafer as a chemical solution. The cleaning process may also include an ozone treatment process in which only ozone-dissolved water is supplied to the semiconductor wafer as a chemical solution. Furthermore, the cleaning process may include both the hydrofluoric acid treatment process and the ozone treatment process, and may be configured such that these processes are performed alternately. Additionally, the cleaning process may include the hydrofluoric acid treatment process, a mixing treatment process in which hydrofluoric acid water and ozone-dissolved water are simultaneously supplied to the semiconductor wafer, and the ozone treatment process, and may be configured such that these processes are performed sequentially.

Examples of the cleaning conditions in the cleaning process include the duration of the final step when the ozone treatment process is the final step in the cleaning process, the concentration of the hydrofluoric acid water, the treatment time in the hydrofluoric acid treatment process, the rotation speed of the semiconductor wafer in the hydrofluoric acid treatment process, the concentration of the ozone-dissolved water, and the duration of the mixing treatment process. As shown in the examples described later, when the cleaning process includes the ozone treatment process as the final step, the thickness of the chemical oxide film formed on the surface of the semiconductor wafer during the cleaning process can be adjusted by changing the duration of the final step.

Further, as shown in the examples described later, when the cleaning process includes the hydrofluoric acid treatment process, the mixing treatment process, and the ozone treatment process, and is configured to sequentially perform these processes, the surface condition of the chemical oxide film formed on the surface of the semiconductor wafer after cleaning can be adjusted by changing the duration of the mixing treatment process (or the ratio of the duration of the mixing treatment process to the total duration of the cleaning process).

Further, as shown in the examples described later, when the cleaning process includes the hydrofluoric acid treatment process and the ozone treatment process, and these processes are repeated such that the final process is the ozone treatment process, the surface condition of the chemical oxide film formed on the surface of the semiconductor wafer after cleaning can be adjusted by changing the duration of the final hydrofluoric acid treatment process.

Further, as shown in the examples described later, when the cleaning process includes the hydrofluoric acid treatment process and the ozone treatment process, and these processes are repeated such that the final process is the ozone treatment process, the surface condition of the chemical oxide film formed on the surface of the semiconductor wafer after cleaning can be adjusted by changing the rotation speed of the semiconductor wafer during the final hydrofluoric acid treatment process.

Further, as shown in the examples described later, when the cleaning process includes the ozone treatment process, the surface condition of the chemical oxide film can also be adjusted by changing the concentration of the ozone dissolved water. Similarly, when the cleaning process includes the hydrofluoric acid treatment process, the surface condition can be adjusted by changing the concentration of the hydrofluoric acid water.

The surface condition of the chemical oxide film can be adjusted by changing two or three of the following parameters in combination: the duration of the mixing treatment process, the duration of the final hydrofluoric acid treatment process, the rotation speed of the semiconductor wafer during the final hydrofluoric acid treatment process, the concentration of the hydrofluoric acid water, and the concentration of the ozone dissolved water.

The correlation between the thickness and surface condition of the chemical oxide film, and the cleaning conditions (cleaning correlation) is obtained. This cleaning correlation is an association between the thickness and surface condition of the chemical oxide film and the cleaning conditions, and it is sufficient that they are correlated in such a manner that, when the thickness and surface condition of the chemical oxide film are determined in the heat treatment condition determining process described later, the cleaning conditions in the cleaning process can be determined so as to obtain such a thickness and surface condition of the chemical oxide film.

### <Heat Treatment Correlation Acquisition Process>

Next, for each of one or more different heat treatment conditions in the heat treatment process, a plurality of semiconductor wafers that have undergone the heat treatment process subsequent to the cleaning process are prepared. For the thermal oxide films formed on the surface of each of the plurality of semiconductor wafers, a heat treatment correlation, which is a correlation between an amount of increase in the thickness of the oxide film after the heat treatment process and the thickness and surface condition of the chemical oxide film, is determined. Here, the “amount of increase in the thickness of the oxide film after the heat treatment process” refers to the difference between the thickness of the oxide film formed in the heat treatment process (thermal oxide film) and the thickness of the oxide film formed in the cleaning process (chemical oxide film).

As described above, the inventors of the present disclosure have found that there is a favorable correlation (heat treatment correlation) between the thickness and surface condition of the chemical oxide film formed on the surface of the semiconductor wafer during the cleaning process, and the amount of increase in the thickness of the oxide film after the heat treatment process with respect to the thermal oxide film formed on the surface of the semiconductor wafers during the heat treatment process. This heat treatment correlation can be expressed, for example, by the following equation (1), where Y is the increase in thickness of the oxide film after the heat treatment process, X1 is the thickness of the chemical oxide film, X2 is the surface condition, and A, B, and C are constants:

$$Y = A \cdot X 1 + B \cdot X 2 + C \qquad ( 1 )$$

When the heat treatment correlation is expressed by the above equation (1), for each of one or more heat treatment conditions, multiple combinations of the thickness of a chemical oxide film, X1, and the surface condition X2, and the amount of increase in the thickness of the oxide film after the heat treatment process, Y, are used to perform multiple regression analysis, with X1 and X2 as explanatory variables and Y as a objective variable, thereby obtaining the constants A, B, and C in advance. Accordingly, once the heat treatment condition is determined in the heat treatment condition determination process described later, the corresponding constants A, B, and C can be determined, and equation (1) corresponding to the determined heat treatment condition can be obtained.

It should be noted that, in obtaining the heat treatment correlation, the thickness of the oxide film after the heat treatment process, Z, may be used in place of the amount of increase in the thickness of the oxide film after the heat treatment process, Y, and a correlation expression may be formulated between the thickness of the oxide film after the heat treatment process, Z, and the thickness of the chemical oxide film, X1, and the surface condition X2. In this case, since Z=Y+X1, the thickness of the oxide film after the heat treatment process, Z, can be expressed by the following equation (2):

$$Z = ( A + 1 ) X 1 + B \cdot X 2 + C \qquad ( 2 )$$

### <Heat Treatment Condition Determination Process>

Subsequently, the heat treatment conditions in the heat treatment process are determined, and a target thickness of the thermal oxide film to be formed on the surface of the semiconductor wafer under the determined heat treatment conditions is also determined. The heat treatment conditions may be selected and determined from one or more heat treatment conditions for which the heat treatment correlation has been obtained in the heat treatment correlation acquisition process. By determining the heat treatment conditions in the heat treatment process, the constants A, B, and C in the above equation (1), for example, can be determined, and the heat treatment correlation corresponding to the determined heat treatment conditions can be obtained. The target thickness may be selected and determined from the thicknesses of the thermal oxide films used when the heat treatment correlation was obtained for the determined heat treatment conditions, or it may be arbitrarily determined.

### <Cleaning Condition Determination Process>

Then, based on the heat treatment correlation and the cleaning correlation, cleaning conditions are determined such that the thickness of the thermal oxide film to be formed on the surface of the semiconductor wafer in the heat treatment process under the determined heat treatment conditions becomes the above-mentioned target thickness. In this cleaning condition determination process, first, by inputting the target thickness of the thermal oxide film determined in the previous process (the heat treatment condition determination process) into the heat treatment correlation corresponding to the determined heat treatment conditions, a plurality of combinations of the thickness and surface condition of the chemical oxide film to be formed in the cleaning process are derived such that the thermal oxide film to be formed in the heat treatment process has the target thickness. Next, one of the combinations that can be easily realized under the cleaning conditions is selected from among the multiple combinations of the thickness and surface condition of the chemical oxide film. Then, by referring to the cleaning correlation, the cleaning conditions under which the desired thickness and surface condition of the chemical oxide film can be obtained in the cleaning process are determined. The cleaning conditions may be selected and determined from among the multiple cleaning conditions used when obtaining the cleaning correlation in the cleaning correlation acquisition process. In this way, cleaning conditions can be determined such that the thickness of the thermal oxide film to be formed on the surface of the semiconductor wafer in the heat treatment process becomes the target thickness.

### (Method for Cleaning Semiconductor Wafer)

The method for cleaning a semiconductor wafer according to the present disclosure is characterized by cleaning a semiconductor wafer under the cleaning conditions determined by the above-described method for determining cleaning conditions for a semiconductor wafer according to the present disclosure.

As described above, according to the method for determining cleaning conditions for a semiconductor wafer of the present disclosure, it is possible to determine cleaning conditions that allow for favorable control of the thickness of the thermal oxide film to be formed on the surface of the semiconductor wafer during the heat treatment process. Therefore, by cleaning the semiconductor wafer under the determined cleaning conditions and subsequently performing a heat treatment under the heat treatment conditions determined in the heat treatment condition determination process, the thickness of the thermal oxide film to be formed on the surface of the semiconductor wafer can be favorably controlled. That is, the thermal oxide film can be formed with suppressed variation from the target thickness.

The semiconductor wafer to be cleaned is not particularly limited and may be a semiconductor wafer made of silicon, germanium, or a compound semiconductor (such as GaAs, GaN, or SiC). Among these, silicon wafers can be cleaned particularly effectively.

### EXAMPLES

Hereinafter, embodiments of the present disclosure will be described; however, the present disclosure is not limited to these embodiments.

### <<Relationship Between Duration of Final Step (Ozone Treatment Process) and Thickness of Chemical Oxide Film>>

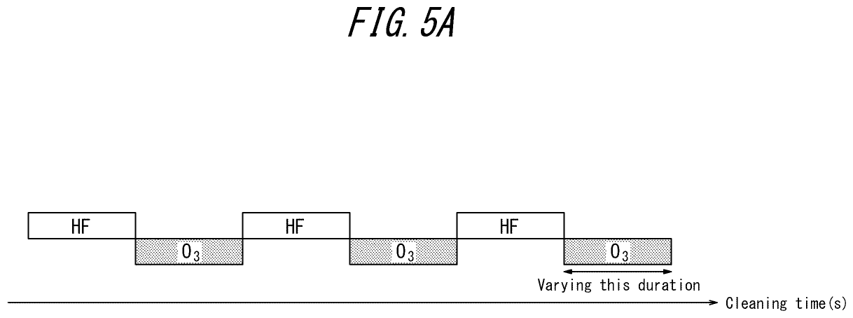

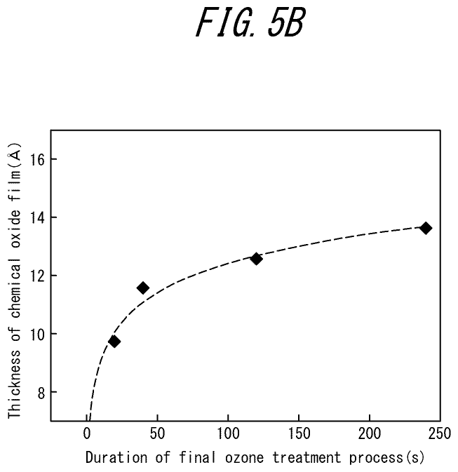

As illustrated in FIG. 5(a), a hydrofluoric acid treatment process, in which only hydrofluoric acid water (with a concentration controlled between 1 and 3 mass %) was supplied to a silicon wafer; and an ozone treatment process, in which only ozone-dissolved water (with a concentration of 25 ppm) was supplied to the silicon wafer, were alternately repeated three times as the cleaning process. In this process, the final step was set as the ozone treatment process, and the duration of the final ozone treatment process was varied in different conditions. After the cleaning process was completed, the thickness of the chemical oxide film formed on the surface of the silicon wafer was measured by ellipsometry. The relationship between the duration of the final ozone treatment process and the thickness of the chemical oxide film is given in FIG. 5(b).

As is clear from FIG. 5(b), the longer the duration of the final ozone treatment process, the greater the thickness of the chemical oxide film formed on the surface of the silicon wafer. This indicates that the thickness of the chemical oxide film can be adjusted by changing the duration of the final ozone treatment process.

### <<Relationship Between Time Ratio of Mixing Treatment Process and Surface Condition of Chemical Oxide Film>>

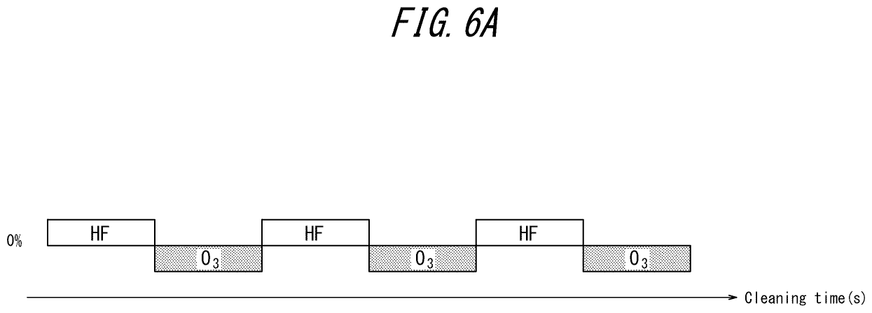

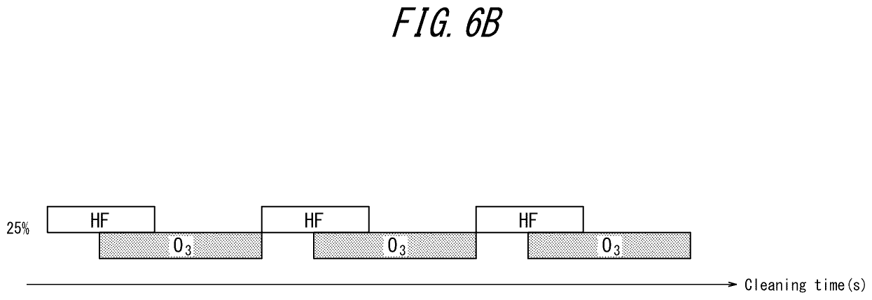

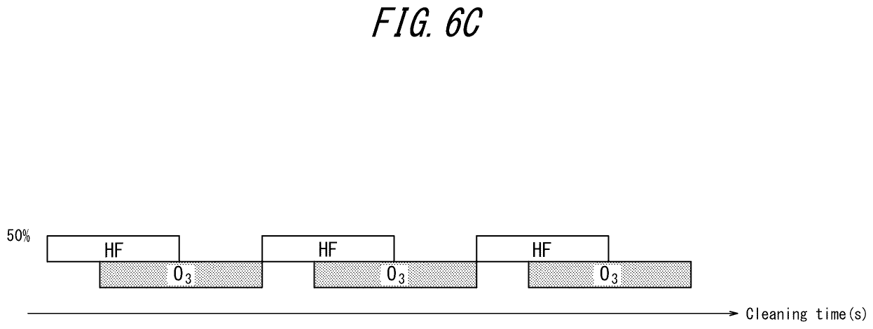

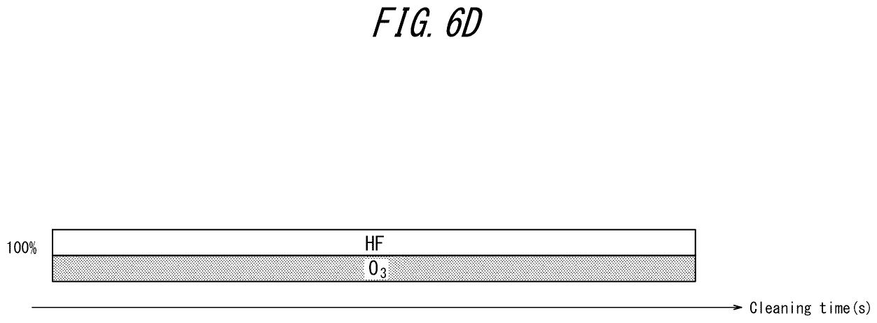

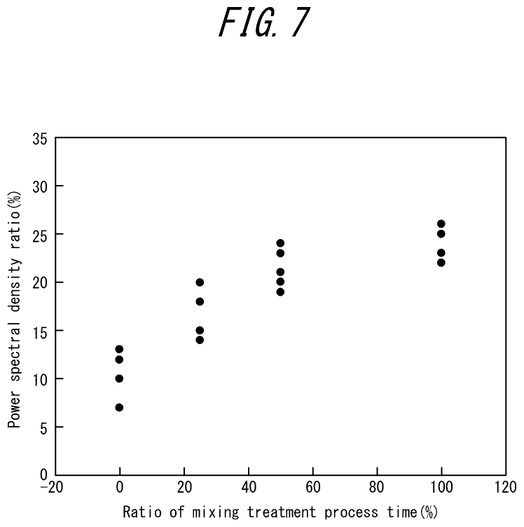

As the cleaning process, a hydrofluoric acid treatment process, in which only hydrofluoric acid water (with a concentration controlled between 1 to 3 mass %) is supplied to a silicon wafer; a mixing treatment process in which both hydrofluoric acid water and ozone-dissolved water (25 ppm concentration) are simultaneously supplied to the silicon wafer; and an ozone treatment process in which only ozone-dissolved water is supplied to the silicon wafer, were carried out. In this case, the time ratio of the mixing treatment process to the entire cleaning process was set to 0% (FIG. 6(a)), 25% (FIG. 6(b)), 50% (FIG. 6(c)), and 100% (FIG. 6(d)), respectively, and the cleaning process was conducted for each condition. For each of the above cases, five silicon wafers were cleaned, and the power spectral density ratio was measured using AFM. The relationship between the time ratio of the mixing treatment process and the power spectral density ratio is given in FIG. 7.

As is apparent from FIG. 7, the power spectral density ratio increases as the time ratio of the mixing treatment process increases, indicating that the surface condition of the chemical oxide film can be adjusted by changing the time ratio of the mixing treatment process.

### <<Relationship Between Duration of Final Hydrofluoric Acid Treatment Process and Surface Condition of Chemical Oxide Film>>

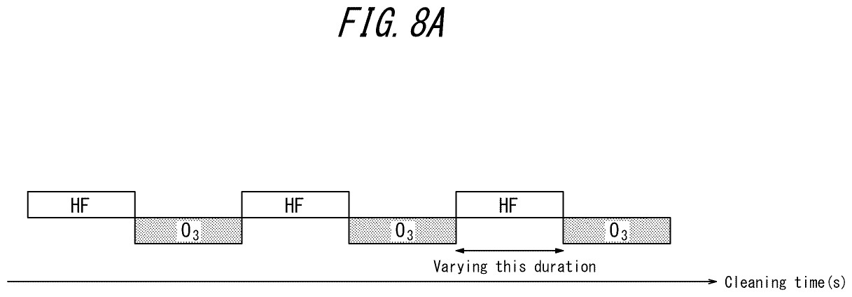

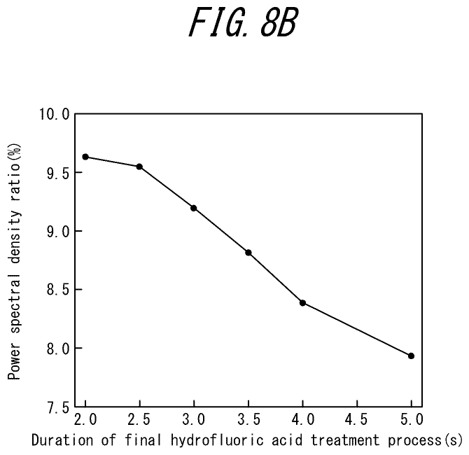

As illustrated in FIG. 8(a), a hydrofluoric acid treatment process, in which only hydrofluoric acid water (with a concentration controlled between 0.5 and 3 mass %) was supplied to a silicon wafer; and an ozone treatment process, in which only ozone-dissolved water (at a concentration of 25 ppm) was supplied to the silicon wafer, were alternately repeated three times as the cleaning process. In this case, the final step was set as the ozone treatment process, and the duration of the final hydrofluoric acid treatment process was varied during the cleaning process. After completion of the cleaning process, the power spectral density ratio was measured using AFM. The relationship between the duration of the final hydrofluoric acid treatment process and the power spectral density ratio is given in FIG. 8(b).

As is apparent from FIG. 8(b), as the duration of the final hydrofluoric acid treatment process increases, the power spectral density ratio decreases, indicating that the surface condition of the chemical oxide film can be adjusted by changing the duration of the final hydrofluoric acid treatment process. By adjusting the duration of the final hydrofluoric acid treatment process, the surface condition of the semiconductor wafer can be adjusted in a relatively short period of time.

It should be noted that although the power spectral density ratio is used as the surface condition of the chemical oxide film in FIG. 8(b), Haze may also be used. Haze can be measured, for example, using a Surfscan SP2 manufactured by KLA-Tencor.

### <<Relationship Between Rotational Speed of Semiconductor Wafer in Final Hydrofluoric Acid Treatment Process and Surface Condition of Chemical Oxide Film>>

As illustrated in FIG. 8(a), a hydrofluoric acid treatment process, in which only hydrofluoric acid water (with a concentration controlled between 0.5 and 3 mass %) is supplied to a silicon wafer; and an ozone treatment process, in which only ozone-dissolved water (with a concentration of 25 ppm) is supplied to the silicon wafer, were alternately repeated three times as the cleaning process. In this case, the final step was the ozone treatment process, and the duration of the final hydrofluoric acid treatment process was set to 3 seconds. The cleaning process was conducted by varying the rotational speed of the semiconductor wafer during the final hydrofluoric acid treatment process between 100 rpm and 500 rpm. After completion of the cleaning process, Haze was measured using AFM and a Surfscan SP2 manufactured by KLA-Tencor. As a result, the increase in the Haze value compared to that of the silicon wafer prior to the cleaning process was 0.025 ppm at 100 rpm, 0.020 ppm at 300 rpm, and 0.016 ppm at 500 rpm.

### <<Relationship Between Ozone Concentration in Ozone-Dissolved Water and Surface Condition of Chemical Oxide Film>>

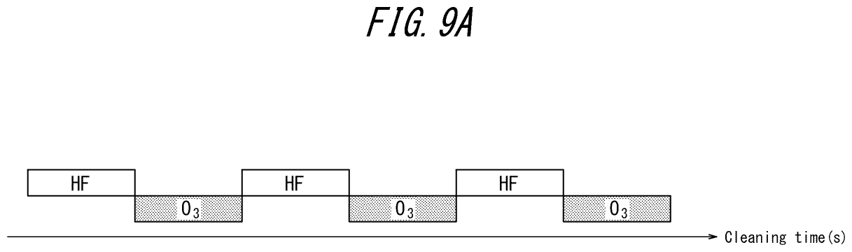

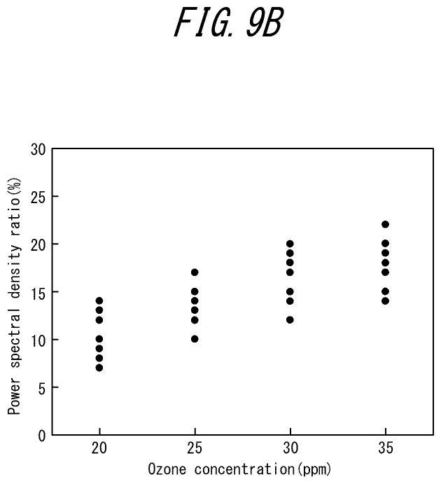

As illustrated in FIG. 9(a), a hydrofluoric acid treatment process, in which only hydrofluoric acid water (with a concentration controlled between 1 and 3 mass %) was supplied to a silicon wafer; and an ozone treatment process, in which only ozone-dissolved water (with an ozone concentration of 20 ppm) was supplied to the silicon wafer, were alternately repeated three times as the cleaning process. The same cleaning process was also performed with the ozone concentration in the ozone-dissolved water set to 25 ppm, 30 ppm, and 35 ppm. After the cleaning process was completed, the power spectral density ratio of the chemical oxide film formed on the surface of the silicon wafer was measured using AFM. The relationship between the ozone concentration in the ozone-dissolved water and the power spectral density ratio is given in FIG. 9(b).

As is apparent from FIG. 9(b), as the concentration of ozone in the ozone-dissolved water increases, the power spectral density ratio also increases, indicating that the surface condition of the chemical oxide film can be adjusted by changing the ozone concentration in the ozone-dissolved water.

### Example 1

In accordance with the flowchart illustrated in FIG. 3, the cleaning conditions for silicon wafers were determined. First, 194 silicon wafers were prepared, each having undergone a cleaning process comprising the hydrofluoric acid treatment process, the mixing treatment process, and the ozone treatment process, with the final step being the ozone treatment process. It should be noted that the cleaning conditions of the cleaning process differed for each of the 194 silicon wafers. Specifically, at least one of the following parameters was different: the duration of the final ozone treatment process, the duration of the mixing treatment process, and the ozone concentration in the ozone-dissolved water used in the ozone treatment process.

For each of the 194 silicon wafers that had undergone the above-described cleaning process, the thickness of the chemical oxide film formed on the wafer surface was measured using ellipsometry, and the power spectral density (in the wavelength range of 3.9 nm to 10 nm) was measured using AFM. From these measurements, the correlation between the thickness of the chemical oxide film X1 (Å) and the power spectral density ratio (X2(%), in the wavelength range of 3.9 nm to 100 nm), and the cleaning conditions were determined (cleaning correlation determination process). Next, each silicon wafer was introduced into a heat treatment furnace and heat treated under the following conditions: oxidizing atmosphere (dry O₂, i.e., 100% dry oxygen), 800° C., and 50 minutes. The thickness of the thermal oxide film formed on the surface of each silicon wafer after the heat treatment was measured using ellipsometry, and the increase in the thickness of the oxide film, Y (Å), was determined. Subsequently, multiple regression analysis was performed using the data obtained for the thickness X1 (Å) and the power spectral density ratio X2(%) of the chemical oxide film, and the increase in thickness Y (Å) of the oxide film, and the constants A, B, and C in equation (1) were determined. As a result, the following equation (3) was obtained as the heat treatment correlation (heat treatment correlation acquisition process).

$$Y = - 0.4254 X 1 + 0.09 \; 60 X 2 + 48.99 \qquad ( 3 )$$

By inputting the thickness of the chemical oxide film, X1 (Å), and the power spectral density ratio X2(%) into the above equation (3), it is possible to predict the increase in thickness of the oxide film after the heat treatment process, Y (Å).

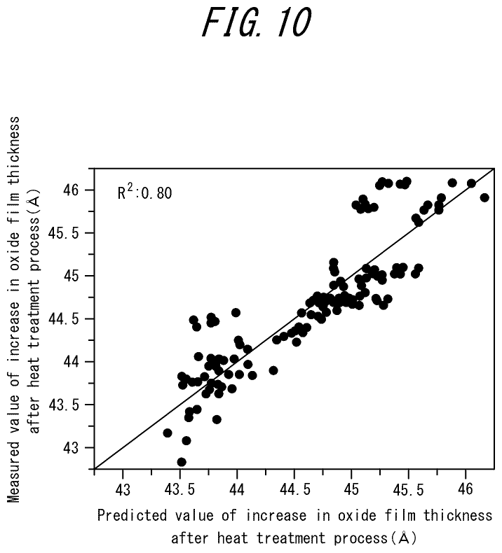

FIG. 10 presents the relationship between the predicted values and the measured values of the increase in the thickness of the oxide film after the heat treatment process. The correlation coefficient is 0.80, indicating that there is a good correlation between the predicted values and the actual measured values of the increase in thickness of the oxide film after the heat treatment process.

Subsequently, the heat treatment conditions for the heat treatment process were determined, and the target thickness of the thermal oxide film to be formed under these heat treatment conditions was set to 45 Å (heat treatment condition determination process). Then, the thickness of the chemical oxide film and the power spectral density corresponding to the target thickness were determined, and based on the determined thickness of the chemical oxide film and the power spectral density, the cleaning conditions were determined (cleaning condition determination process). In this way, the cleaning conditions for silicon wafers that yield a thermal oxide film with the target thickness were determined.

### Conventional Example

Thirty silicon wafers were prepared and divided into three groups. Using three different cleaning apparatuses, each group underwent a cleaning process comprising the hydrofluoric acid treatment process, the mixing treatment process, and the ozone treatment process, with the final step being the ozone treatment process. The cleaning conditions for the final ozone treatment process were set to a process time of 30 seconds and an ozone concentration of 25 ppm for all three cleaning apparatuses. Subsequently, each silicon wafer was subjected to a heat treatment process under the conditions of an oxidizing atmosphere (dry O₂, i.e., 100% dry oxygen), at 800° C. for 50 minutes, using a heat treatment furnace. The target thickness of the thermal oxide film was set to 45 Å. After the heat treatment process, the thickness of the thermal oxide film formed on the surface of each silicon wafer was measured by ellipsometry.

### Example 2

Using the same three cleaning apparatuses as in the Conventional Example, a cleaning process and a heat treatment process were carried out in the same manner as in the conventional example. However, for each of the three apparatuses, the cleaning conditions for the cleaning process were determined in accordance with the flowchart illustrated in FIG. 3. The determined cleaning conditions were as follows: for the apparatus with apparatus ID 1, the process time for the final ozone treatment process was 75 seconds and the ozone concentration was 20 ppm; for the apparatus with apparatus ID 2, the process time was 15 seconds and the ozone concentration was 30 ppm; and for the apparatus with apparatus ID 3, the process time was 30 seconds and the ozone concentration was 25 ppm. Thirty silicon wafers were divided into three groups, and the cleaning process was performed using the three apparatuses under the respective determined cleaning conditions. All other conditions were identical to those in the Conventional Example.

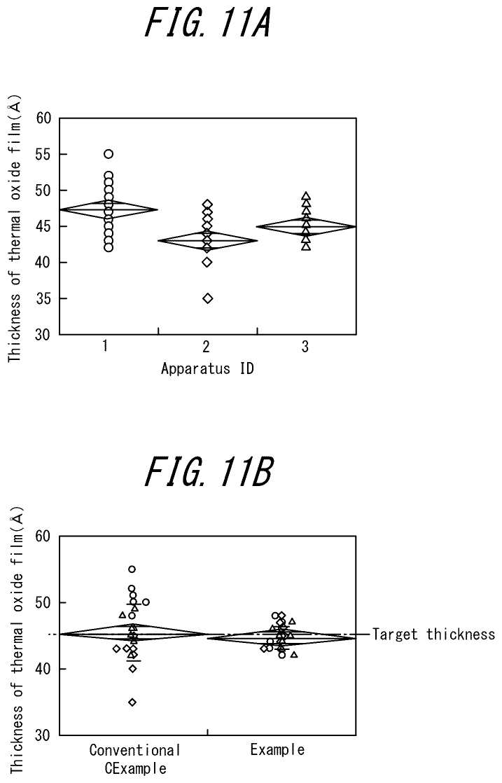

FIG. 11(a) presents the thickness of the thermal oxide film formed during the heat treatment process for each of the three apparatuses in the Conventional Example. As is apparent from FIG. 11(a), the degree of variation in the oxide film thickness differs depending on the cleaning apparatus.

FIG. 11(b) presents the thickness of the thermal oxide film formed in Conventional Example and Example 2. As is apparent from FIG. 11(b), the variation in the oxide film thickness in Example 2 is smaller than that in Conventional Example, relative to the target thickness. This demonstrates that the present disclosure enables improved control of the oxide film thickness formed during the heat treatment process.

### INDUSTRIAL APPLICABILITY

According to the present disclosure, the thickness of the thermal oxide film can be effectively controlled. As a result, device yield can be improved, thereby achieving increased production efficiency and reduced waste.

1. A method for determining cleaning conditions of a semiconductor wafer, the method comprising:
a cleaning correlation acquisition process of preparing a plurality of semiconductor wafers that have undergone a cleaning process under a plurality of cleaning conditions, and obtaining a cleaning correlation, which is a correlation between a thickness and a surface condition of a chemical oxide film formed on a surface of each of the plurality of semiconductor wafers and the cleaning conditions;
a heat treatment correlation acquisition process of, for each of one or more different heat treatment conditions in a heat treatment process, preparing a plurality of semiconductor wafers that have undergone the heat treatment process subsequent to the cleaning process, and obtaining a heat treatment correlation, which is a correlation between an amount of increase in thickness of an oxide film after the heat treatment process with respect to a thermal oxide film formed on the surface of each of the plurality of semiconductor wafers and the thickness and the surface condition of the chemical oxide film;
a heat treatment condition determination process of determining the heat treatment conditions in the heat treatment process and determining a target thickness of the thermal oxide film to be formed on the surface of the semiconductor wafer in the heat treatment process under the determined heat treatment conditions; and
a cleaning condition determination process of determining the cleaning conditions such that the thickness of the thermal oxide film to be formed on the surface of the semiconductor wafer in the heat treatment process under the determined heat treatment conditions becomes the target thickness, based on the heat treatment correlation and the cleaning correlation.

2. The method for determining cleaning conditions of a semiconductor wafer according to claim 1, wherein the surface condition is indicated by a power spectral density of surface roughness measured using an atomic force microscope.

3. The method for determining cleaning conditions of a semiconductor wafer according to claim 1, wherein the heat treatment correlation is expressed by the following Equation (1), in which Y is the amount of increase in the thickness of the oxide film after the heat treatment process, X1 is the thickness of the chemical oxide film, X2 is the surface condition, and A, B, and C are constants:
$$Y = A \cdot X 1 + B \cdot X 2 + C . \qquad ( 1 )$$

4. The method for determining cleaning conditions of a semiconductor wafer according to claim 3, wherein
the constants A, B, and C are obtained in advance for each of the one or more heat treatment conditions, and
the constants A, B, and C are determined in accordance with the heat treatment conditions determined in the heat treatment condition determination process.

5. The method for determining cleaning conditions of a semiconductor wafer according to claim 1, wherein
the cleaning process includes, as at least a final step of the cleaning process, an ozone treatment process in which only ozone-dissolved water is supplied to the semiconductor wafer as a chemical solution, and wherein
among the plurality of cleaning conditions, a duration of the final step is different.

6. The method for determining cleaning conditions of a semiconductor wafer according to claim 1, wherein
the cleaning process includes:
a hydrofluoric acid treatment process in which only hydrofluoric acid water is supplied to the semiconductor wafer as a chemical solution;
a mixing treatment process in which hydrofluoric acid water and ozone-dissolved water are simultaneously supplied to the semiconductor wafer as chemical solutions; and
an ozone treatment process in which only ozone-dissolved water is supplied to the semiconductor wafer as a chemical solution, and wherein
among the plurality of cleaning conditions, a duration of the mixing treatment process is different.

7. The method for determining cleaning conditions of a semiconductor wafer according to claim 1, wherein
the cleaning process includes:
a hydrofluoric acid treatment process in which only hydrofluoric acid water is supplied to the semiconductor wafer as a chemical solution; and
an ozone treatment process in which only ozone-dissolved water is supplied to the semiconductor wafer as a chemical solution, and wherein
among the plurality of cleaning conditions, a concentration of the ozone-dissolved water is different.

8. The method for determining cleaning conditions of a semiconductor wafer according to claim 1, wherein
the cleaning process includes:
a hydrofluoric acid treatment process in which only hydrofluoric acid water is supplied to the semiconductor wafer as a chemical solution; and
an ozone treatment process in which only ozone-dissolved water is supplied to the semiconductor wafer as a chemical solution, and wherein
among the plurality of cleaning conditions, a duration of a final hydrofluoric acid treatment process is different.

9. The method for determining cleaning conditions of a semiconductor wafer according to claim 1, wherein
the cleaning process includes:
a hydrofluoric acid treatment process in which only hydrofluoric acid water is supplied to the semiconductor wafer as a chemical solution; and
an ozone treatment process in which only ozone-dissolved water is supplied to the semiconductor wafer as a chemical solution, and wherein
among the plurality of cleaning conditions, a rotation speed of the semiconductor wafer during a final hydrofluoric acid treatment process is different.

10. A method for cleaning a semiconductor wafer, wherein a semiconductor wafer is cleaned under the cleaning conditions determined by the method for determining cleaning conditions of a semiconductor wafer according to claim 1.

11. The method for cleaning a semiconductor wafer according to claim 8, wherein the semiconductor wafer is a silicon wafer.
